(19) United States
(12) Patent Application Publication
(10) Pub. No.: US 2026/0362772 A1
(43) Pub. Date: Nov. 12, 2026

(54) SEMICONDUCTOR DEVICE STRUCTURE WITH SEMICONDUCTOR NANOSTRUCTURES

(71) Applicant: Taiwan Semiconductor Manufacturing Company, Ltd., Hsinchu (TW)

(72) Inventors: Chun-Ming KO, Hsinchu City (TW); Wei-Yang LEE, Taipei City (TW); Che-Lun CHANG, Hsinchu (TW); Bo-Yu LAI, Taipei City (TW)

(73) Assignee: Taiwan Semiconductor Manufacturing Company, Ltd., Hsinchu (TW)

(21) Appl. No.: 19/746,981

(22) Filed: Jul. 20, 2026

Related U.S. Application Data
(63) Continuation of application No. 18/889,962, filed on Sep. 19, 2024.
(60) Provisional application No. 63/652,343, filed on May 28, 2024.

(51) Int. Cl. H10D 64/01; H10D 30/01; H10D 30/43; H10D 30/67; H10D 62/10; H10W 90/00

(52) U.S. Cl. CPC H10D 64/018; H10D 30/014; H10D 30/43; H10D 30/6735; H10D 30/6757; H10D 62/121; H10D 64/017; H10W 90/792

(57) ABSTRACT

A semiconductor device structure is provided. The semiconductor device structure includes multiple semiconductor nanostructures, and the semiconductor nanostructures exhibit a line width roughness under about 0.9 nm. The semiconductor device structure also includes a gate stack wrapped around the semiconductor nanostructures. The gate stack has a gate dielectric layer and a titanium-containing work function layer. The semiconductor device structure further includes a first epitaxial structure and a second epitaxial structure. One or more of the semiconductor nanostructures are sandwiched between the first epitaxial structure and the second epitaxial structure. In addition, the semiconductor device structure includes a dielectric layer laterally surrounding the gate stack and covering the epitaxial structure. The gate dielectric layer has a greater dielectric constant than that of the dielectric layer.

### PRIORITY CLAIM AND CROSS-REFERENCE

This application is a Continuation application of U.S. patent application Ser. No. 18/889,962, filed on Sep. 19, 2024, which claims the benefit of U.S. Provisional Application No. 63/652,343, filed on May 28, 2024, the entirety of which are incorporated by reference herein.

### BACKGROUND

The semiconductor integrated circuit (IC) industry has experienced rapid growth. Technological advances in IC materials and design have produced generations of ICs. Each generation has smaller and more complex circuits than the previous generation.

Over the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, these advances have increased the complexity of processing and manufacturing ICs. Since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1B are top views of various stages of a process for forming a portion of a semiconductor device structure, in accordance with some embodiments.

FIGS. 2A-2D are cross-sectional views of various stages of a process for forming a portion of a semiconductor device structure, in accordance with some embodiments.

FIGS. 3A-3N are cross-sectional views of various stages of a process for forming a portion of a semiconductor device structure, in accordance with some embodiments.

FIG. 4 is a cross-sectional view of an intermediate stage of a process for forming a portion of a semiconductor device structure, in accordance with some embodiments.

FIG. 5 is a cross-sectional view of an intermediate stage of a process for forming a portion of a semiconductor device structure, in accordance with some embodiments.

FIGS. 6A-6E are cross-sectional views of various stages of a process for forming a portion of a semiconductor device structure, in accordance with some embodiments.

FIGS. 7A-7E are cross-sectional views of various stages of a process for forming a portion of a semiconductor device structure, in accordance with some embodiments.

FIGS. 8A-8C are cross-sectional views of various stages of a process for forming a portion of a semiconductor device structure, in accordance with some embodiments.

FIG. 9A is a cross-sectional view of a portion of a semiconductor device structure, in accordance with some embodiments.

FIG. 9B is a cross-sectional view of a portion of a semiconductor device structure, in accordance with some embodiments.

FIGS. 10A-10B are cross-sectional views of various stages of a process for forming a portion of a semiconductor device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. Where applicable, the term “substantially” may also relate to 90% or higher, such as 95% or higher, especially 99% or higher, including 100% of what is specified. Furthermore, terms such as "substantially parallel" or "substantially perpendicular" are to be interpreted as not to exclude insignificant deviation from the specified arrangement and may include for example deviations of up to 10 degrees in some embodiments. The word "substantially" does not exclude "completely" e.g. a composition which is "substantially free" from Y may be completely free from Y in some embodiments.

Terms such as "about" in conjunction with a specific distance or size are to be interpreted so as not to exclude insignificant deviation from the specified distance or size and may include for example deviations of up to 10% of what is specified in some embodiments. The term "about" in relation to a numerical value x may mean x ±5 or 10% of what is specified in some embodiments.

Embodiments of the disclosure may relate to FinFET structure having fins. The fins may be patterned using any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. However, the fins may be formed using one or more other applicable processes.

Embodiments of the disclosure may relate to the gate all around (GAA) transistor structures. The GAA structure may be patterned using any suitable method. For example, the structures may be patterned using one or more photolithography processes, including double-patterning or multi-patterning processes. In some embodiments, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

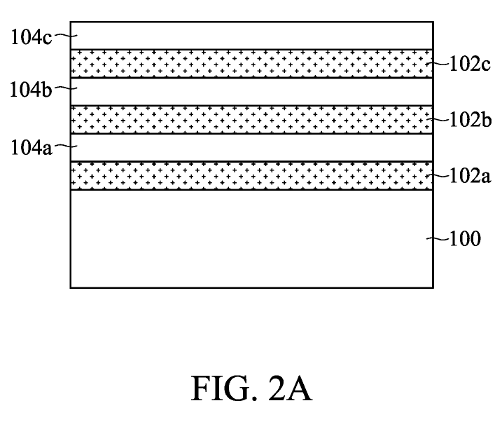

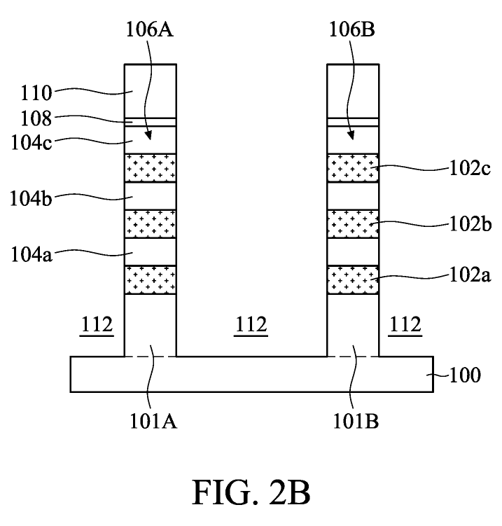

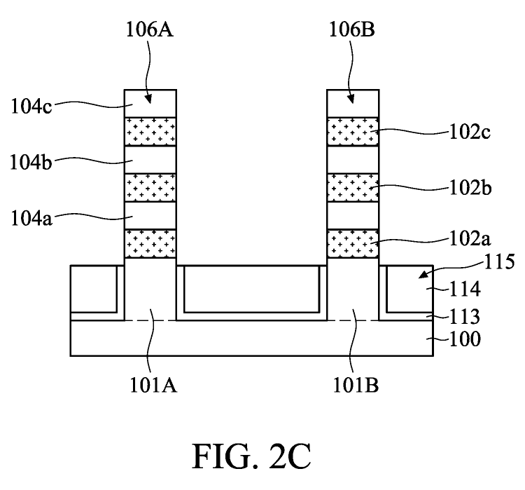

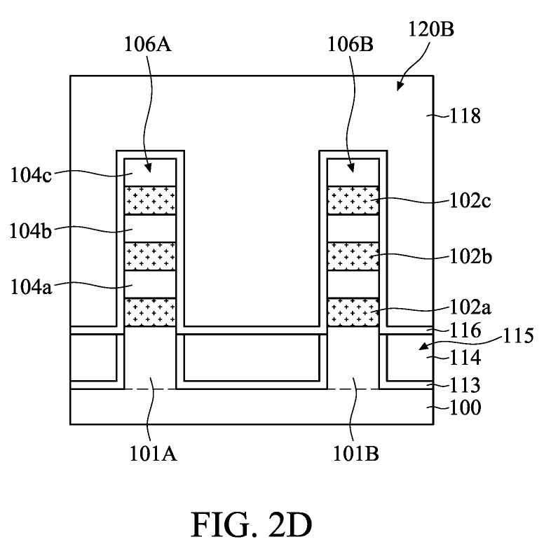

FIGS. 2A-2D are cross-sectional views of various stages of a process for forming a portion of a semiconductor device structure, in accordance with some embodiments. As shown in FIG. 2A, a semiconductor substrate 100 is received or provided. In some embodiments, the semiconductor substrate 100 is a bulk semiconductor substrate, such as a semiconductor wafer. The semiconductor substrate 100 may include silicon or other elementary semiconductor materials such as germanium. The semiconductor substrate 100 may be un-doped or doped (e.g., p-type, n-type, or a combination thereof). In some embodiments, the semiconductor substrate 100 includes an epitaxially grown semiconductor layer on a dielectric layer. The epitaxially grown semiconductor layer may be made of silicon germanium, silicon, germanium, one or more other suitable materials, or a combination thereof.

In some other embodiments, the semiconductor substrate 100 includes a compound semiconductor. For example, the compound semiconductor includes one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

In some embodiments, the semiconductor substrate 100 is an active layer of a semiconductor-on-insulator (SOI) substrate. The SOI substrate may be fabricated using a separation by implantation of oxygen (SIMOX) process, a wafer bonding process, another applicable method, or a combination thereof. In some other embodiments, the semiconductor substrate 100 includes a multi-layered structure. For example, the semiconductor substrate 100 includes a silicon-germanium layer formed on a bulk silicon layer.

As shown in FIG. 2A, a semiconductor stack having multiple semiconductor layers is formed over the semiconductor substrate 100, in accordance with some embodiments. In some embodiments, the semiconductor stack includes multiple semiconductor layers 102a, 102b, and 102c. The semiconductor stack also includes multiple semiconductor layers 104a, 104b, and 104c. In some embodiments, the semiconductor layers 102a-102c and the semiconductor layers 104a-104c are laid out in an alternating manner, as shown in FIG. 2A.

In some embodiments, the semiconductor layers 102a-102c function as sacrificial layers that will be removed in a subsequent process to release the semiconductor layers 104a-104c. The semiconductor layers 104a-104c that are released form multiple semiconductor nanostructures, which may serve as the channel structures of one or more transistors.

In some embodiments, the semiconductor layers 104a-104c that will be used to form channel structures are made of a material that is different than that of the semiconductor layers 102a-102c. In some embodiments, the semiconductor layers 104a-104c are made of or include silicon, another suitable material, or a combination thereof. In some embodiments, the semiconductor layers 102a-102c are made of or include silicon germanium. Due to the different compositions, different etching selectivity and/or different oxidation rates during subsequent processing may be achieved between the semiconductor layers 102a-102c and the semiconductor layers 104a-104c.

The present disclosure contemplates that the semiconductor layers 102a-102c and the semiconductor layers 104a-104c include any combination of semiconductor materials that can provide desired etching selectivity, desired oxidation rate differences, and/or desired performance characteristics (e.g., materials that maximize current flow).

In some embodiments, the semiconductor layers 102a-102c and 104a-104c are formed using multiple epitaxial growth operations. Each of the semiconductor layers 102a-102c and 104a-104c may be formed using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, one or more other applicable processes, or a combination thereof.

In some embodiments, the semiconductor layers 102a-102c and 104a-104c are grown in-situ in the same process chamber. In some embodiments, the growth of the semiconductor layers 102a-102c and 104a-104c are alternately and sequentially performed in the same process chamber to complete the formation of the semiconductor stack. In some embodiments, the vacuum of the process chamber is not broken before the epitaxial growth of the semiconductor stack is accomplished.

Afterwards, hard mask elements are formed over the semiconductor stack to assist in a subsequent patterning of the semiconductor stack. Each of the hard mask elements may include a first mask layer 108 and a second mask layer 110. The first mask layer 108 and the second mask layer 110 may be made of different materials. One or more photolithography processes and one or more etching processes are used to pattern the semiconductor stack into multiple fin structures. The fin structures may be patterned by any suitable method. For example, the fin structures may be patterned using one or more photolithography processes, including double-patterning or multi-patterning processes. Double-patterning or multi-patterning processes may combine photolithography and self-aligned processes, allowing patterns to be created that have, for example, pitches smaller than what is otherwise obtainable using a single, direct photolithography process.

The semiconductor stack is partially removed to form multiple fin structures (including fin structures 106A and 106B) and multiple trenches 112, as shown in FIG. 2B in accordance with some embodiments. Each of the fin structures 106A-106B may include portions of the semiconductor layers 102a-102c and 104a-104c and multiple semiconductor fins (including semiconductor fins 101A and 101B), as shown in FIG. 2B. The semiconductor substrate 100 may also be partially removed during the etching process that forms the fin structures. Protruding portions of the semiconductor substrate 100 that remain form the semiconductor fins 101A and 101B.

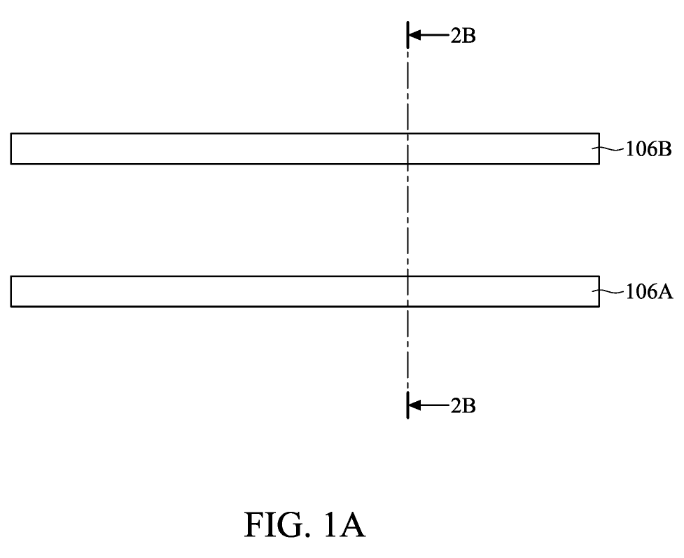

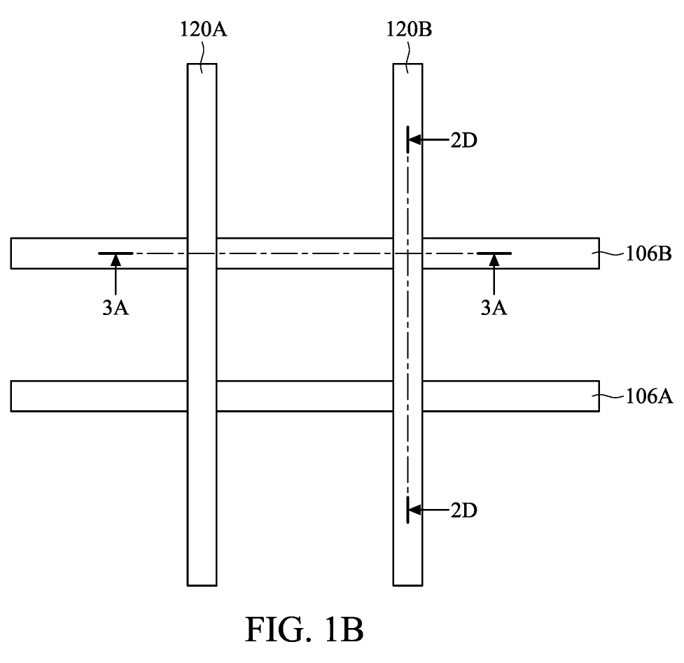

FIGS. 1A-1B are top views of various stages of a process for forming a portion of a semiconductor device structure, in accordance with some embodiments. As shown in FIG. 1A, multiple fin structures 106A and 106B are formed, in accordance with some embodiments. In some embodiments, the fin structures 106A and 106B are oriented lengthwise. In some embodiments, the extending directions of the fin structures 106A and 106B are substantially parallel to each other, as shown in FIG. 1A. In some embodiments, FIG. 2B is a cross-sectional view of the structure taken along the line 2B-2B in FIG. 1A.

Afterwards, as shown in FIG. 2C, an isolation structure 115 is formed to surround lower portions of the fin structures 106A and 106B, in accordance with some embodiments. In some embodiments, the isolation structure 115 includes dielectric fillings 114 and a liner layer 113 that is adjacent to the semiconductor fins 101A and 101B.

In some embodiments, one or more dielectric layers for forming the dielectric fillings 114 are deposited over the fin structures 106A and 106B and the semiconductor substrate 100. The dielectric layers may be made of or include silicon oxide, silicon oxynitride, borosilicate glass (BSG), phosphoric silicate glass (PSG), borophosphosilicate glass (BPSG), fluorinated silicate glass (FSG), low-k material, porous dielectric material, one or more other suitable materials, or a combination thereof. The liner layer 113 may be made of or include silicon nitride, silicon oxynitride, silicon carbide, silicon oxycarbide, one or more other suitable materials, or a combination thereof. The dielectric layers and the liner layer 113 may be deposited using a flowable chemical vapor deposition (FCVD) process, an atomic layer deposition (ALD) process, a chemical vapor deposition (CVD) process, one or more other applicable processes, or a combination thereof.

Afterwards, a planarization process is used to partially remove the dielectric layers and the liner layer 113. The hard mask elements (including the first mask layer 108 and the second mask layer 110) may also function as a stop layer of the planarization process. The planarization process may include a chemical mechanical polishing (CMP) process, a grinding process, a dry polishing process, an etching process, one or more other applicable processes, or a combination thereof.

Afterwards, one or more etching back processes are used to partially remove the dielectric layers and the liner layer 113. As a result, the remaining portion of the dielectric layers forms the dielectric fillings 114 of the isolation structure 115. Upper portions of the fin structures 106A and 106B protrude from the top surface of the isolation structure 115, as shown in FIG. 2C.

In some embodiments, the etching back process for forming the isolation structure 115 is carefully controlled to ensure that the topmost surface of the isolation structure 115 is positioned at a suitable height level, as shown in FIG. 2C. In some embodiments, the topmost surface of the isolation structure 115 is below the bottommost surface of the semiconductor layer 102a that functions as a sacrificial layer. The side edges of the bottommost sacrificial layer (i.e., the semiconductor layer 102a) are thus exposed without being covered by the isolation structure 115, thereby facilitating the subsequent removal process of the semiconductor layers 102a-102c.

Afterwards, the hard mask elements (including the first mask layer 108 and the second mask layer 110) are removed. Alternatively, in some other embodiments, the hard mask elements are removed or consumed during the planarization process and/or the etching back process that forms the isolation structure 115.

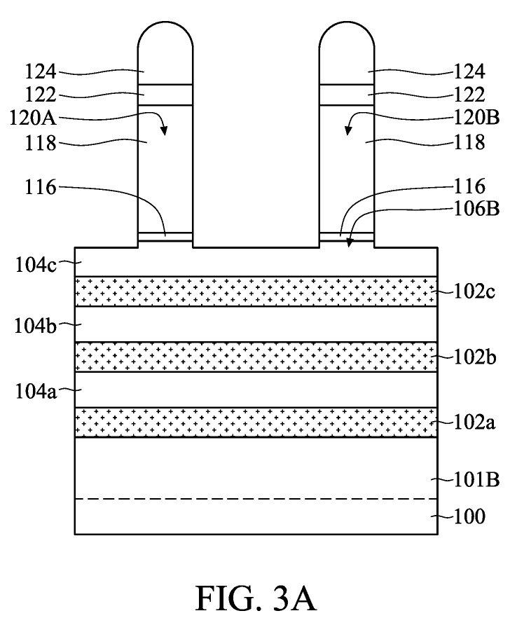

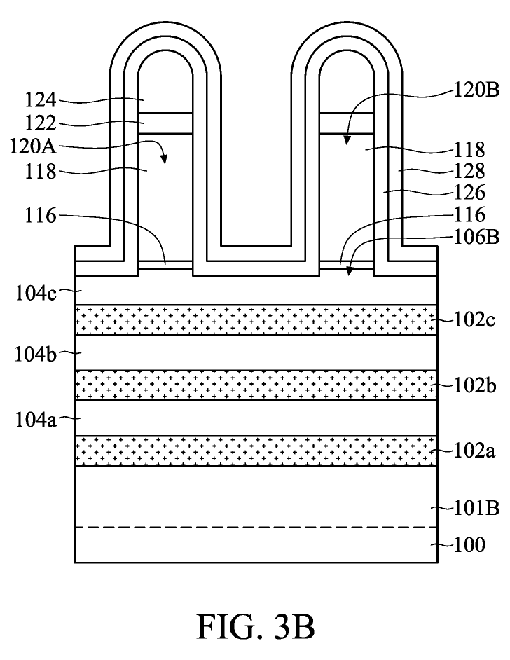

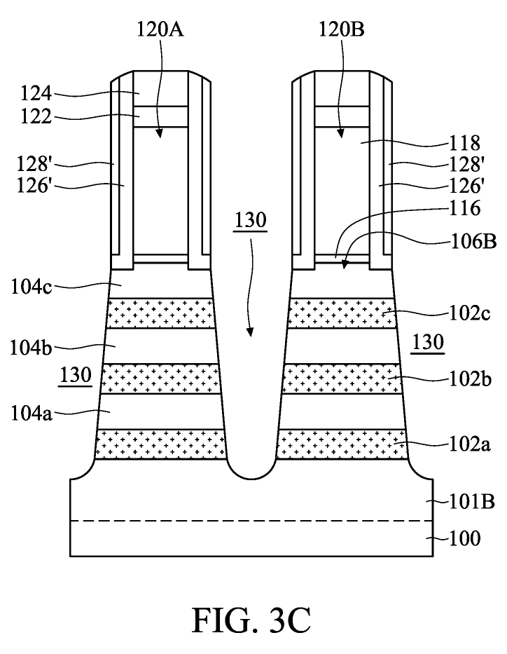

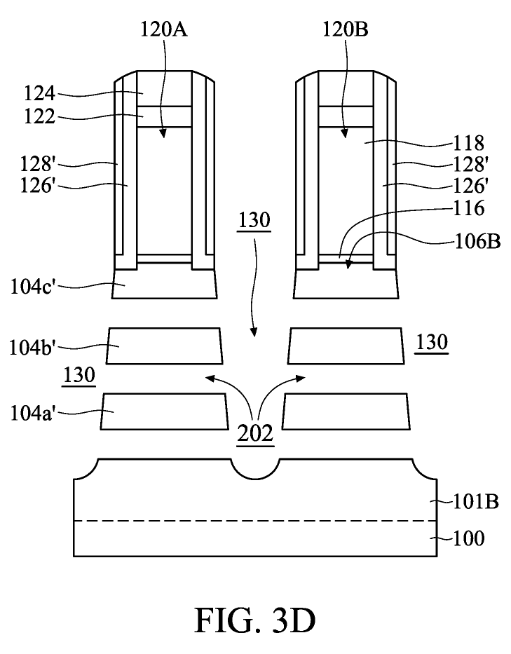

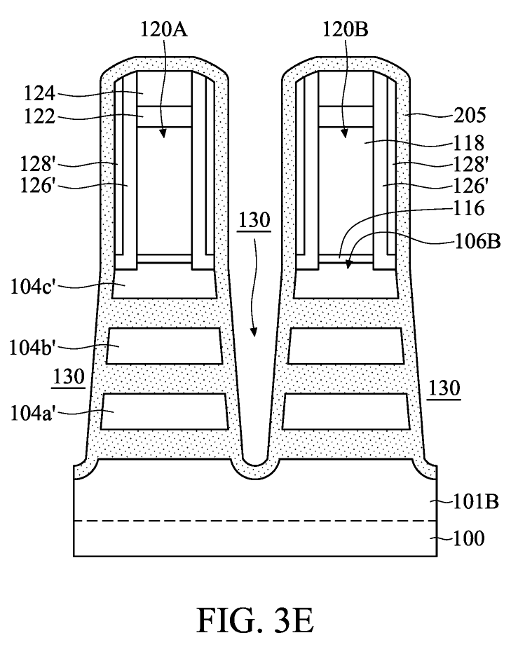

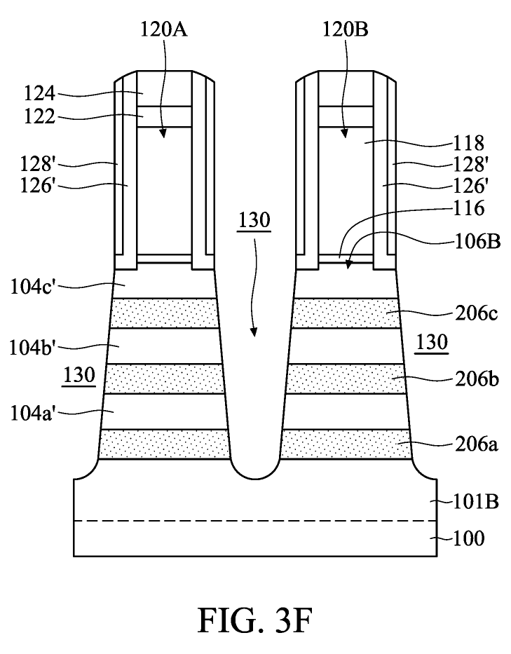

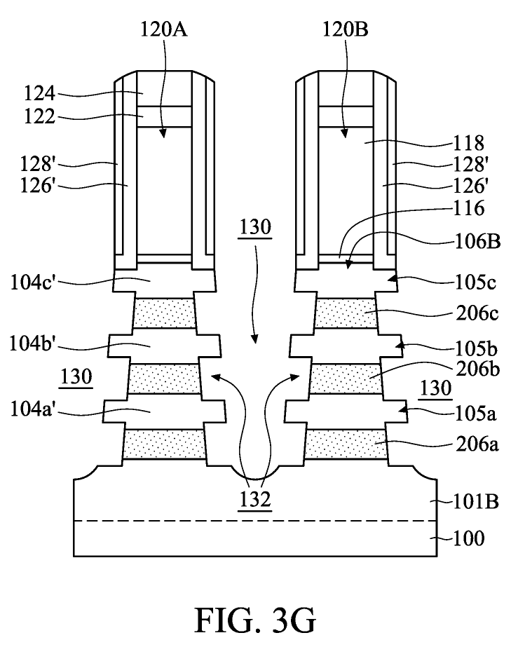

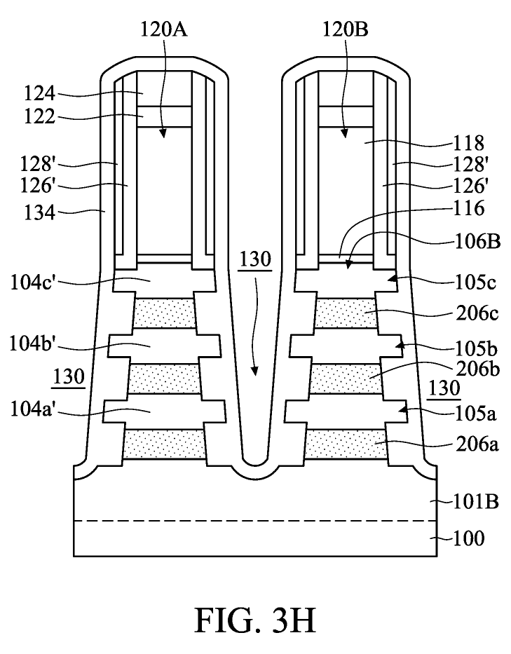

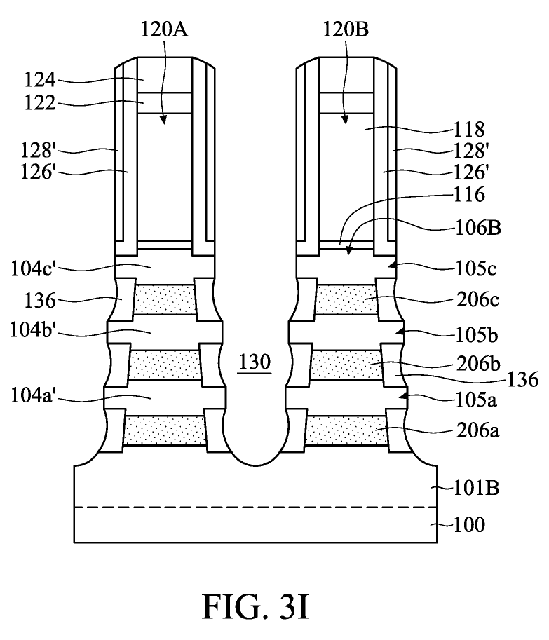

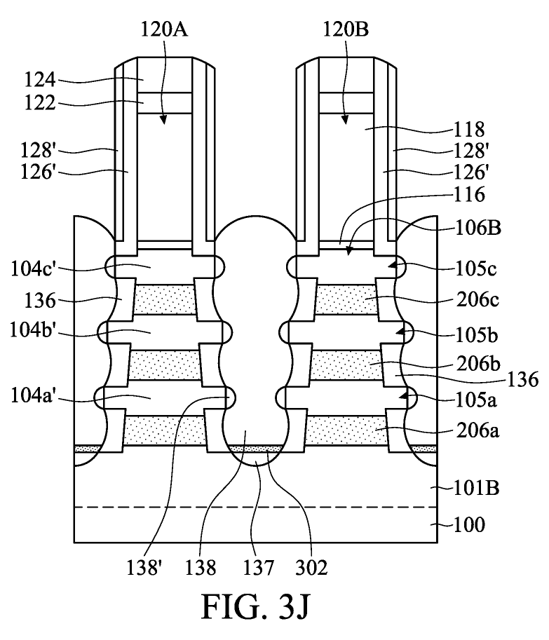

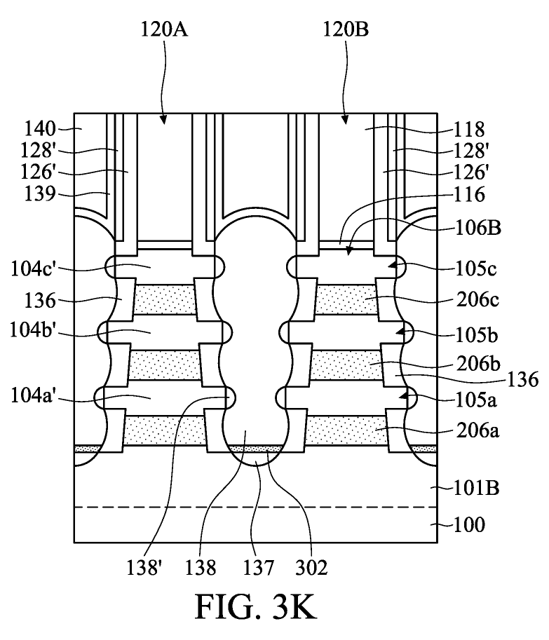

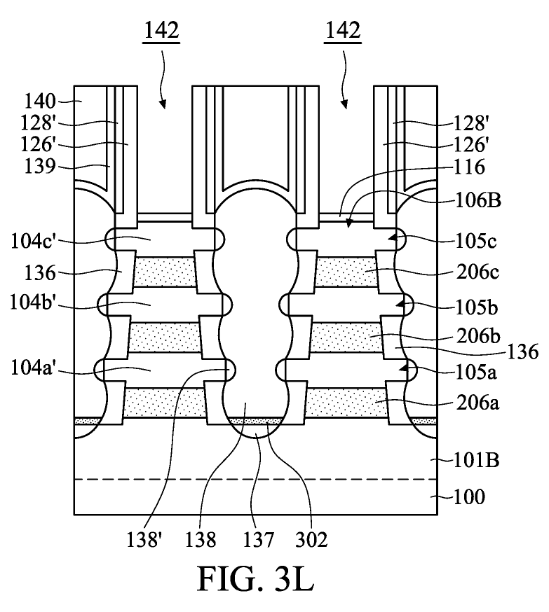

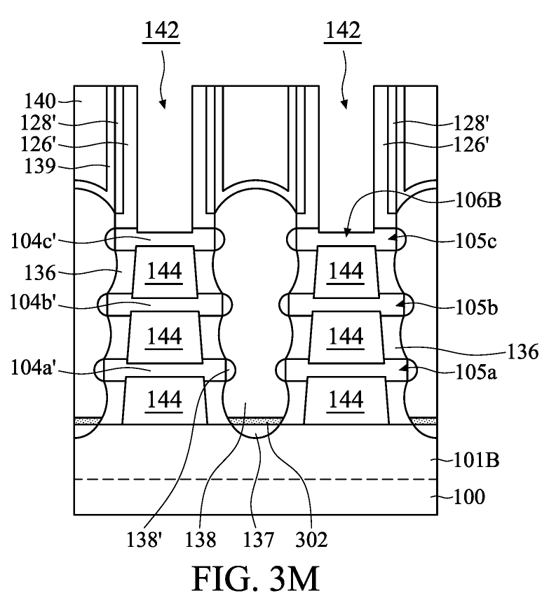

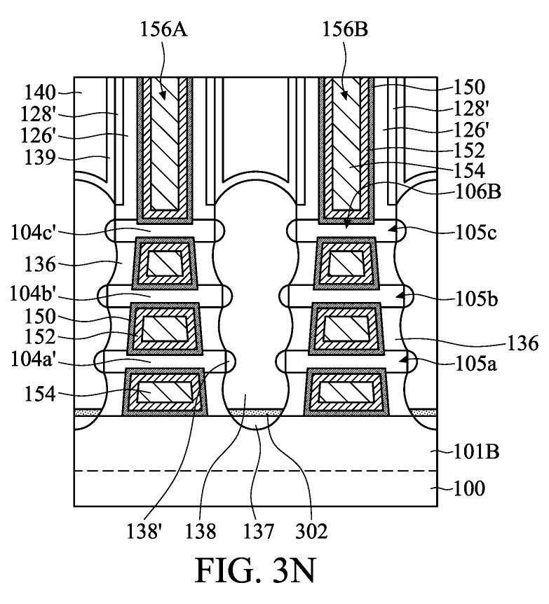

Afterwards, dummy gate stacks 120A and 120B are formed to extend across the fin structures 106A and 106B, as shown in FIG. 1B in accordance with some embodiments. In some embodiments, FIG. 2D is a cross-sectional view of the structure taken along the line 2D-2D in FIG. 1B. FIGS. 3A-3N are cross-sectional views of various stages of a process for forming portions of a semiconductor device structure, in accordance with some embodiments. In some embodiments, FIG. 3A is a cross-sectional view of the structure taken along the lines 3A-3A in FIG. 1B.

As shown in FIGS. 1B, 2D, and 3A, the dummy gate stacks 120A and 120B partially cover and extend across the fin structures 106A and 106B, in accordance with some embodiments. As shown in FIG. 2D, the dummy gate stack 120B extends across and is wrapped around the fin structures 106A and 106B. As shown in FIG. 1B, other portions of the fin structures 106A and 106B are exposed without being covered by the dummy gate stack 120A and 120B.

As shown in FIGS. 2D and 3A, each of the dummy gate stacks 120A and 120B includes a dummy gate dielectric layer 116 and a dummy gate electrode 118. The dummy gate dielectric layer 116 may be made of or include silicon oxide or another suitable material. The dummy gate electrodes 118 may be made of or include polysilicon or another suitable material.

In some embodiments, a dummy gate dielectric material layer and a dummy gate electrode layer are sequentially deposited over the isolation structure 115 and the fin structures 106A and 106B. The dummy gate dielectric material layer may be deposited using an ALD process, a CVD process, one or more other applicable processes, or a combination thereof. The dummy gate electrode layer may be deposited using a CVD process. Afterwards, the dummy gate dielectric material layer and the dummy gate electrode layer are patterned to form the dummy gate stacks 120A and 120B.

In some embodiments, hard mask elements 122 and 124 are used to assist in the patterning process for forming the dummy gate stacks 120A and 120B. With the hard mask elements 122 and 124 as an etching mask, one or more etching processes are used to partially remove the dummy gate dielectric material layer and the dummy gate electrode layer. As a result, remaining portions of the dummy gate dielectric material layer and the dummy gate electrode layer form the dummy gate stacks 120A and 120B.

As shown in FIG. 3B, spacer layers 126 and 128 are afterwards deposited over the dummy gate stacks 120A and 120B and the fin structure 106B, in accordance with some embodiments. The spacer layers 126 and 128 extend along the tops and sidewalls of the dummy gate stacks 120A and 120B, as shown in FIG. 3B. The spacer layers 126 and 128 also extend along the top of the fin structure 106B, as shown in FIG. 3B.

In some embodiments, the spacer layers 126 and 128 are made of different materials. In some other embodiments, the spacer layers 126 and 128 are made of the same material. The spacer layers 126 and 128 may be made of or include silicon nitride, silicon carbide, silicon oxycarbide, carbon-containing silicon oxynitride, silicon oxide, another suitable material, or a combination thereof. In some embodiments, each of the spacer layers 126 and 128 is a single layer. In some other embodiments, one or both of the spacer layers 126 and 128 include multiple sub-layers. Some of the sub-layers may be made of different materials. Some of the sub-layers may be made of similar materials with different compositions. For example, one of the sub-layers may have a greater atomic concentration of carbon than other sub-layers. The spacer layers 126 and 128 may be sequentially deposited using a CVD process, an ALD process, a physical vapor deposition (PVD) process, another applicable process, or a combination thereof.

As shown in FIG. 3C, the spacer layers 126 and 128 are partially removed, in accordance with some embodiments. One or more anisotropic etching processes may be used to partially remove the spacer layers 126 and 128. As a result, remaining portions of the spacer layers 126 and 128 form gate spacers 126’ and 128’, respectively. The gate spacers 126’ and 128’ extend along the sidewalls of the dummy gate stacks 120A and 120B, as shown in FIG. 3C.

Afterwards, the fin structures 106A and 106B are partially removed to form recesses used for containing subsequently formed epitaxial structures. As shown in FIG. 3C, the fin structure 106B is partially removed to form recesses 130, in accordance with some embodiments. The recesses 130 expose the side edges of the semiconductor layers 104a-104c on which epitaxial structures (such as source/drain structures) will subsequently be formed. A source/drain structure may refer to a source structure or a drain structure, individually or collectively, depending upon the context.

One or more etching processes may be used to form the recesses 130. In some embodiments, a dry etching process is used to form the recesses 130. Alternatively, a wet etching process may be used to form the recesses 130. In some embodiments, each of the recesses 130 penetrates into the fin structure 106B. In some embodiments, the recesses 130 further extend into the semiconductor fin 101B, as shown in FIG. 3C. In some embodiments, the gate spacers 126’ and 128’ and the recesses 130 are simultaneously formed using the same etching process.

In some embodiments, each of the recesses 130 has slanted sidewalls. Upper portions of the recesses 130 are larger (or wider) than lower portions of the recesses 130. In these cases, due to the profile of the recesses 130, an upper semiconductor layer (such as the semiconductor layer 104c) is shorter than a lower semiconductor layer (such as the semiconductor layer 104b).

However, embodiments of the disclosure have many variations. In some other embodiments, the recesses 130 have substantially vertical sidewalls. In these cases, due to the profile of the recesses 130, an upper semiconductor layer (such as the semiconductor layer 104c) is substantially as wide as a lower semiconductor layer (such as the semiconductor layer 104b).

Afterwards, the semiconductor layers 102a-102c, which serve as sacrificial layers, are removed. As a result, the structure shown in FIG. 3D is formed, in accordance with some embodiments. One or more etching processes may be used to remove the semiconductor layers 102a-102c. After the removal of the semiconductor layers 102a-102c, multiple recesses 202 are formed, as shown in FIG. 3D. The remaining portions of the semiconductor layers 104a-104c that are released from the semiconductor layers 102a-102c form multiple semiconductor nanostructures 104a’, 104b’, and 104c’, as shown in FIG. 3D. With the support of the dummy gate stacks 120A and 120B, the semiconductor nanostructures 104a’-104c’ are securely held in place.

As shown in FIG. 3E, a dielectric layer 205 is deposited to overfill the recesses 202 and to surround the semiconductor nanostructures 104a’-104c’, in accordance with some embodiments. The dielectric layer 205 may also extend over the top and sidewalls of the dummy gate stacks 120A and 120B. The dielectric layer 205 may be made of an oxide material, a nitride material, another suitable material, or a combination thereof. The dielectric layer 205 may be made of or include silicon oxide, silicon oxynitride, aluminum oxide, silicon nitride, another suitable material, or a combination thereof.

In some embodiments, the dielectric layer 205 is a single layer. In some other embodiments, the dielectric layer 205 includes multiple sub-layers. In some embodiments, the sub-layers of the dielectric layer 205 are made of the same material. In some other embodiments, some of the sub-layers of the dielectric layer 205 are made of different materials.

The dielectric layer 205 may be deposited using a CVD process, an ALD process, a flowable chemical vapor deposition (FCVD) process, another applicable process, or a combination thereof. In some embodiments, the formation of the dielectric layer 205 further involves one or more etching processes that are used to tune the profile of the deposited sub-layers of the dielectric layer 205.

As shown in FIG. 3F, multiple dielectric nanostructures 206a, 206b, and 206c are formed in the recesses 202, in accordance with some embodiments. In some embodiments, the dielectric layer 205 is partially removed using one or more etching processes. The portion of the dielectric layer 205 outside of the recesses 202 are removed. As a result, the remaining portions of the dielectric layer 205 form multiple dielectric nanostructures 206a, 206b, and 206c, as shown in FIG. 3F.

Afterwards, as shown in FIG. 3G, the dielectric nanostructures 206a-206c are partially removed to pull back the side edges of the dielectric nanostructures 206a-206c, in accordance with some embodiments. One or more etching processes may be used to partially remove the dielectric nanostructures 206a-206c. As a result, the side edges of the dielectric nanostructures 206a-206c retreat from the side edges of the semiconductor nanostructures 104a’-104c’. As shown in FIG. 3G, recesses 132 are formed due to the lateral etching of the dielectric nanostructures 206a-206c. The recesses 132 may be used to contain inner spacers that will be formed later.

In some embodiment, the semiconductor nanostructures 104a’-104c’ are also slightly etched during the lateral etching of the dielectric nanostructures 206a-206c. As a result, edge portions of the semiconductor nanostructures 104a’-104c’ are partially etched and thus shrink to form edge portions 105a-105c, as shown in FIG. 3G. As shown in FIG. 3G, each of the edge portions 105a-105c of the semiconductor nanostructures 104a’-104c’ is thinner than the corresponding inner portion of the semiconductor nanostructures 104a’-104c’.

Embodiments of the disclosure are not limited thereto. Many variations and/or modifications can be made to embodiments of the disclosure. In some other embodiments, the semiconductor nanostructures 104a’-104c’ are substantially not etched during the lateral etching of the dielectric nanostructures 206a-206c. As a result, edge portions 105a-105c of the semiconductor nanostructures 104a’-104c’ are substantially not shrunk. In some embodiments, each of the edge portions 105a-105c of the semiconductor nanostructures 104a’-104c’ is substantially as thick as the corresponding inner portion of the semiconductor nanostructures 104a’-104c’.

As shown in FIG. 3H, an insulating layer 134 is deposited over the structure shown in FIG. 3G, in accordance with some embodiments. The insulating layer 134 covers the dummy gate stacks 120A and 120B and fills the recesses 132. The insulating layer 134 may be made of or include carbon-containing silicon nitride (SiCN), carbon-containing silicon oxynitride (SiOCN), carbon-containing silicon oxide (SiOC), silicon oxide, silicon nitride, another suitable material, or a combination thereof.

In some embodiments, the dielectric nanostructures 206a-206c are made of silicon oxide, and the insulating layer 134 is made of carbon-containing silicon oxynitride, silicon nitride, another suitable material, or a combination thereof. In some embodiments, the dielectric nanostructures 206a-206c are made of silicon nitride, and the insulating layer 134 is made of carbon-containing silicon oxynitride, silicon oxide, another suitable material, or a combination thereof. In some embodiments, the dielectric nanostructures 206a-206c are made of silicon oxynitride, and the insulating layer 134 is made of carbon-containing silicon oxynitride, another suitable material, or a combination thereof. In some embodiments, the dielectric nanostructures 206a-206c are made of aluminum oxide, and the insulating layer 134 is made of carbon-containing silicon oxynitride, another suitable material, or a combination thereof.

In some embodiments, the insulating layer 134 is a single layer. In some other embodiments, the insulating layer 134 includes multiple sub-layers. Some of the sub-layers may be made of different materials and/or contain different compositions. The insulating layer 134 may be deposited using a CVD process, an ALD process, another applicable process, or a combination thereof.

As shown in FIG. 3I, an etching process is used to partially remove the insulating layer 134, in accordance with some embodiments. The portions of the insulating layer 134 outside of the recesses 132 are removed. The remaining portions of the insulating layer 134 form inner spacers 136, as shown in FIG. 3I. The etching process may include a dry etching process, a wet etching process, or a combination thereof.

The inner spacers 136 cover the side edges of the dielectric nanostructures 206a-206c, as shown in FIG. 3I. The inner spacers 136 may be used to prevent subsequently formed epitaxial structures (which function as source/drain structures, for example) from being damaged during a subsequent process for removing the dielectric nanostructures 206a-206c. In some embodiments, the inner spacers 136 are made of a low-k material that has a lower dielectric constant than that of silicon oxide. In these cases, the inner spacers 136 may also be used to reduce parasitic capacitance between the subsequently formed source/drain structures and the gate stacks. As a result, the operation speed of the semiconductor device structure may be improved.

In some embodiments, after the etching process for forming the inner spacers 136, portions of the semiconductor fin 101B originally covered by the insulating layer 134 are exposed by the recesses 130, as shown in FIG. 3I. The side edges of the semiconductor nanostructures 104a’-104c’ are also exposed by the recesses 130, as shown in FIG. 3I.

As shown in FIG. 3J, semiconductor separation structures 137 are formed over the bottoms of the recesses 130, in accordance with some embodiments. In some embodiments, the semiconductor separation structures 137 are epitaxial structures that are undoped. In some embodiments, the semiconductor separation structures 137 are substantially free of n-type dopants or p-type dopants. The semiconductor separation structures 137 may help to reduce or prevent current leakage from epitaxial structures that will be formed. The semiconductor separation structures 137 may provide relatively planar surfaces to facilitate the subsequent formation of the epitaxial structures.

The semiconductor separation structures 137 may be made of or include silicon, silicon germanium, another suitable material, or a combination thereof. The semiconductor separation structures 137 may be formed using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, another applicable process, or a combination thereof. In some embodiments, the formation of the semiconductor separation structures 137 involve one or more etching processes that are used to fine-tune the profiles of the semiconductor separation structures 137.

Afterwards, bottom isolation elements 302 are selectively formed on the semiconductor separation structures 137, as shown in FIG. 3J in accordance with some embodiments. The bottom isolation elements 302 may be used to further prevent leakage current between the semiconductor fin 101B and the epitaxial structures that will be formed on the bottom isolation elements 302.

In some embodiments, the bottom isolation elements 302 are made of or include a dielectric material. The dielectric material may include silicon oxide, silicon nitride, carbon-containing silicon nitride, carbon-containing silicon oxynitride, carbon-containing silicon oxide, aluminum oxide, hafnium oxide, another suitable material, or a combination thereof. The formation of the bottom isolation elements 302 may involve one or more deposition processes and one or more patterning processes.

However, embodiments of the disclosure are not limited thereto. Many variations and/or modifications can be made to embodiments of the disclosure. In some other embodiments, the bottom isolation elements 302 and/or the semiconductor separation structures 137 are not formed.

Afterwards, as shown in FIG. 3J, epitaxial structures 138 are formed on the bottom isolation elements 302 and the side edges of the semiconductor nanostructures 104a’-104c’, in accordance with some embodiments. In some embodiments, the top surfaces of the epitaxial structures 138 are higher than the top surface of the dummy gate dielectric layer 116, as shown in FIG. 3J. In some other embodiments, the epitaxial structures 138 are substantially as high as the tops of the edge portions 105c.

In some embodiments, the epitaxial structures 138 connect to the semiconductor nanostructures 104a’-104c’. Each of the semiconductor nanostructures 104a’-104c’ is sandwiched between the epitaxial structures 138. In some embodiments, the epitaxial structures 138 have lightly doped portions 138’ adjacent to the semiconductor nanostructures 104a’-104c’. The dopant concentration of the lightly doped portions 138’ is lower than other portions of the epitaxial structures 138.

In some embodiments, the epitaxial structures 138 are p-type doped regions. The epitaxial structures 138 may include epitaxially grown silicon germanium (SiGe), epitaxially grown silicon, or another suitable epitaxially grown semiconductor material. P-type dopants may include boron, another suitable element, or a combination thereof.

However, embodiments of the disclosure are not limited thereto. In some other embodiments, the epitaxial structures 138 are n-type doped regions. The epitaxial structures 138 may include epitaxially grown silicon, epitaxially grown silicon carbide (SiC), epitaxially grown germanium, or another suitable epitaxially grown semiconductor material. N-type dopants may include phosphor, arsenic, another suitable element, or a combination thereof.

In some embodiments, the epitaxial structures 138 are doped in-situ during their epitaxial growth. The initial reaction gas mixture for forming the epitaxial structures 138 contains dopants. In some other embodiments, the epitaxial structures 138 are not doped during the growth of the epitaxial structures 138. Instead, after the formation of the epitaxial structures 138, the epitaxial structures 138 are doped in a subsequent process. In some embodiments, the doping is achieved by using an ion implantation process, a plasma immersion ion implantation process, a gas and/or solid source diffusion process, another applicable process, or a combination thereof. In some embodiments, the epitaxial structures 138 are further exposed to one or more annealing processes to activate the dopants. For example, a rapid thermal annealing process is used.

In some embodiments, some of the epitaxial structures 138 are p-type doped, and the other epitaxial structures 138 are n-type doped. A patterned mask may be used to assist in the respective formation of the epitaxial structures 138 that are p-type doped and the epitaxial structures 138 that are n-type doped.

In some embodiments, the formation of the epitaxial structures 138 that involves the thermal processes is performed after the semiconductor layers 102a-102c are replaced with the dielectric nanostructures 206a-206c. Therefore, germanium from the semiconductor layers 102a-102c is prevented from diffusing into the nearby semiconductor nanostructures 104a’-104c’ during the formation of the epitaxial structures 138. The semiconductor nanostructures 104a’-104c’ may thus have a low atomic concentration of germanium impurities, enhancing the quality and reliability of the semiconductor nanostructures 104a’-104c’.

As shown in FIG. 3K, a contact etch stop layer 139 and a dielectric layer 140 are formed over the epitaxial structures 138 and the dummy gate stacks 120A and 120B, in accordance with some embodiments. The contact etch stop layer 139 may be made of or include silicon nitride, silicon oxynitride, silicon carbide, carbon-containing silicon nitride, carbon-containing silicon oxynitride, carbon-containing silicon oxide, aluminum oxide, another suitable material, or a combination thereof. The dielectric layer 140 may be made of or include silicon oxide, silicon oxynitride, borosilicate glass (BSG), phosphoric silicate glass (PSG), borophosphosilicate glass (BPSG), fluorinated silicate glass (FSG), low-k material, porous dielectric material, another suitable material, or a combination thereof.

In some embodiments, an etch stop material layer and a dielectric material layer are sequentially deposited over the structure shown in FIG. 3J. The etch stop material layer may be deposited using a CVD process, an ALD process, a PVD process, another applicable process, or a combination thereof. The dielectric material layer may be deposited using an FCVD process, a CVD process, an ALD process, another applicable process, or a combination thereof.

Afterwards, a planarization process is used to partially remove the etch stop material layer and the dielectric material layer. As a result, the remaining portions of the etch stop material layer and the dielectric material layer respectively form the contact etch stop layer 139 and the dielectric layer 140, as shown in FIG. 3K. The planarization process may include a CMP process, a grinding process, an etching process, a dry polishing process, another applicable process, or a combination thereof.

In some embodiments, the hard mask elements 122 and 124 over the dummy gate stacks 120A and 120B are also removed during the planarization process. In some embodiments, after the planarization process, the top surfaces of the contact etch stop layer 139, the dielectric layer 140, and the dummy gate electrodes 118 are substantially level with each other.

Afterwards, as shown in FIG. 3L, the dummy gate electrodes 118 are removed to form trenches 142 using one or more etching processes, in accordance with some embodiments. The trenches 142 are surrounded by the dielectric layer 140. The trenches 142 expose the dummy gate dielectric layer 116.

As shown in FIG. 3M, the dummy gate dielectric layer 116 and the dielectric nanostructures 206a-206c (which function as sacrificial layers) are removed, in accordance with some embodiments. In some embodiments, one or more etching processes are used to remove the dummy gate dielectric layer 116 and the dielectric nanostructures 206a-206c. As a result, recesses 144 are formed, as shown in FIG. 3M.

Due to high etching selectivity, the semiconductor nanostructures 104a’-104c’ are slightly (or substantially not) etched. The semiconductor nanostructures 104a’-104c’ suspended over the semiconductor fin 101B may function as the channel structures of transistors. In some other embodiments, the etchant used for removing the dielectric nanostructures 206a-206c also slightly removes the semiconductor nanostructures 104a’-104c’. As a result, the obtained semiconductor nanostructures 104a’-104c’ become thinner after the removal of the dielectric nanostructures 206a-206c. In some embodiments, the inner portion of each of the semiconductor nanostructures 104a’-104c’ is thinner than the edge portions 105a-105c since the edge portions 105a-105c are surrounded by other elements and thus are prevented from being reached and etched by the etchant.

However, embodiments of the disclosure are not limited thereto. Many variations and/or modifications can be made to embodiments of the disclosure. In some embodiments, the inner portion of each of the semiconductor nanostructures 104a’-104c’ is substantially as thick as the edge portions 105a-105c. In some other embodiments, the inner portion of each of the semiconductor nanostructures 104a’-104c’ is slightly thicker than the edge portions 105a-105c.

After the removal of the dielectric nanostructures 206a-206c (which function as sacrificial layers), the recesses 144 are formed. The recesses 144 connect to the trench 142 and surround each of the semiconductor nanostructures 104a’-104c’. As shown in FIG. 3M, even with the formation of recesses 144 between the semiconductor nanostructures 104a’-104c’, the semiconductor nanostructures 104a’-104c’ remain supported by the neighboring elements, including the epitaxial structures 138 and the inner spacers 136. Therefore, after removing the dummy gate stacks 120A and 120B and the dielectric nanostructures 206a-206c, the released semiconductor nanostructures 104a’-104c’ are prevented from falling.

During the removal of the dielectric nanostructures 206a-206c (which function as sacrificial layers), the inner spacers 136 protect the epitaxial structures 138 from being etched or damaged. The quality and reliability of the semiconductor device structure are improved.

As shown in FIG. 3N, metal gate stacks 156A and 156B are formed to fill the trenches 142, in accordance with some embodiments. The metal gate stacks 156A and 156B further extend into the recesses 144 to wrap around each of the semiconductor nanostructures 104a’-104c’. Each of the metal gate stacks 156A and 156B includes multiple metal gate stack layers. Each of the metal gate stacks 156A and 156B may include a gate dielectric layer 150, a work function layer 152, and a conductive filling 154.

In some embodiments, the formation of the metal gate stacks 156A and 156B involves the deposition of multiple metal gate stack layers over the dielectric layer 140 to fill the trenches 142 and the recesses 144. The metal gate stack layers extend into the recesses 144 to wrap around each of the semiconductor nanostructures 104a’-104c’.

In some embodiments, the gate dielectric layer 150 is made of or includes a dielectric material with high dielectric constant (high-K). The gate dielectric layer 150 may be made of or include hafnium oxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, one or more other suitable high-K materials, or a combination thereof. The gate dielectric layer 150 may be deposited using an ALD process, a CVD process, another applicable process, or a combination thereof.

In some embodiments, before the formation of the gate dielectric layer 150, interfacial layers are formed on the surfaces of the semiconductor nanostructures 104a’-104c’. The interfacial layers are thin layers made of, for example, silicon oxide. In some embodiments, the interfacial layers are formed by applying an oxidizing agent to the surfaces of the semiconductor nanostructures 104a’-104c’. For example, a hydrogen peroxide-containing liquid may be provided or applied to the surfaces of the semiconductor nanostructures 104a’-104c’ so as to form the interfacial layers.

The work function layer 152 may be used to provide the desired work function for transistors to enhance device performance including improved threshold voltage. In some embodiments, the work function layer 152 is used for forming a PMOS device. The work function layer 152 is a p-type work function layer. The p-type work function layer is capable of providing a work function value suitable for the device, such as equal to or greater than about 4.8 eV.

The p-type work function layer may include metal, metal carbide, metal nitride, another suitable material, or a combination thereof. For example, the p-type metal includes tantalum nitride, tungsten nitride, titanium nitride, another suitable material, or a combination thereof.

In some other embodiments, the work function layer 152 is used for forming an NMOS device. The work function layer 152 is an n-type work function layer. The n-type work function layer is capable of providing a work function value suitable for the device, such as equal to or less than about 4.5 eV.

The n-type work function layer may include metal, metal carbide, metal nitride, or a combination thereof. In some embodiments, the n-type work function layer is an aluminum-containing layer. The aluminum-containing layer may be made of or include TiAlC, TiAlO, TiAlN, another suitable material, or a combination thereof.

The work function layer 152 may also be made of or include hafnium, zirconium, titanium, tantalum, aluminum, metal carbides (e.g., hafnium carbide, zirconium carbide, titanium carbide, aluminum carbide), aluminides, ruthenium, palladium, platinum, cobalt, nickel, conductive metal oxides, or a combinations thereof. The thickness and/or the compositions of the work function layer 152 may be fine-tuned to adjust the work function level.

The work function layer 152 may be deposited over the gate dielectric layer 150 using an ALD process, a CVD process, a PVD process, an electroplating process, an electrochemical plating process, another applicable process, or a combination thereof.

In some embodiments, a barrier layer is formed before the work function layer 152 to interface the gate dielectric layer 150 with the subsequently formed work function layer 152. The barrier layer may also be used to prevent diffusion between the gate dielectric layer 150 and the subsequently formed work function layer 152. The barrier layer may be made of or include a metal-containing material. The metal-containing material may include titanium nitride, tantalum nitride, another suitable material, or a combination thereof. The barrier layer may be deposited using an ALD process, a CVD process, a PVD process, an electroplating process, an electrochemical plating process, another applicable process, or a combination thereof.

In some embodiments, different portions of the metal gate stacks 156A and 156B are wrapped around semiconductor nanostructures 104a’-104c’ of different devices including PMOS devices and NMOS devices. Different portions of the metal gate stacks 156A and 156B thus have different types of work function layer or different combinations of work functions layers. Multiple deposition processes and multiple patterning processes may be used to selectively form different work function layers at different portions of the metal gate stacks 156A and 156B.

In some embodiments, the conductive fillings 154 are made of or include a metal material. The metal material may include tungsten, ruthenium, aluminum, copper, cobalt, another suitable material, or a combination thereof. A conductive layer used for forming the conductive filling may be deposited over the work function layer using a CVD process, an ALD process, a PVD process, an electroplating process, an electrochemical plating process, a spin coating process, another applicable process, or a combination thereof.

In some embodiments, a blocking layer is formed over the work function layer 152 before the formation of the conductive layer used for forming the conductive filling. The blocking layer may be used to prevent the subsequently formed conductive layer from diffusing or penetrating into the work function layer. The blocking layer may be made of or include tantalum nitride, titanium nitride, another suitable material, or a combination thereof. The blocking layer may be deposited using an ALD process, a PVD process, an electroplating process, an electrochemical plating process, another applicable process, or a combination thereof.

Afterwards, a planarization process is performed to remove the portions of the metal gate stack layers outside of the trenches 142 and the recesses 144, in accordance with some embodiments. As a result, the remaining portions of the metal gate stack layers form the metal gate stacks 156A and 156B, as shown in FIG. 3N.

In some embodiments, the conductive filling 154 does not extend into the recesses 144 since the recesses 144 are small and have been filled with other elements such as the gate dielectric layer 150 and the work function layer 152. In some embodiments, even if the conductive filling 154 does not extend into the recesses 144 between the semiconductor nanostructures 104a’-104c’, the conductive filling 154 may fill into the trenches 142 above the semiconductor nanostructure 104c’. However, embodiments of the disclosure are not limited thereto. In some other embodiments, a portion of the conductive filling 154 extends into some of the recesses 144, such as the lower recesses 144 with larger space.

In some embodiments, the semiconductor layers 102a-102c are replaced with dielectric nanostructures 206a-206c before the formation of the epitaxial structures 138. During the thermal processes for forming the epitaxial structures 138, the semiconductor layers 102a-102c containing germanium had already been removed. Consequently, the diffusion of germanium impurities from the semiconductor layers 102a-102c to the semiconductor nanostructures 104a’-104c’ is significantly reduced or prevented. As a result, the semiconductor nanostructures 104a’-104c’ have a low atomic concentration of germanium impurities, enhancing the quality and reliability of the semiconductor nanostructures 104a’-104c’. The semiconductor nanostructures 104a’-104c’ may have an atomic concentration of germanium impurities that is within a range from about 0% to about 0.01%.

In some embodiments, the semiconductor nanostructures 104a’-104c’ are primarily composed of silicon, giving them high etching selectivity compared to the dielectric nanostructures 206a-206c. As a result, no over-etching or only minimal over-etching is required to remove the dielectric nanostructures 206a-206c and to release the semiconductor nanostructures 104a’-104c’. This significantly reduces the surface roughness of the semiconductor nanostructures 104a’-104c’, which in turn decreases current crowding and surface scattering. As a result, the electrical properties, including carrier mobility, of the semiconductor nanostructures 104a’-104c’ are enhanced.

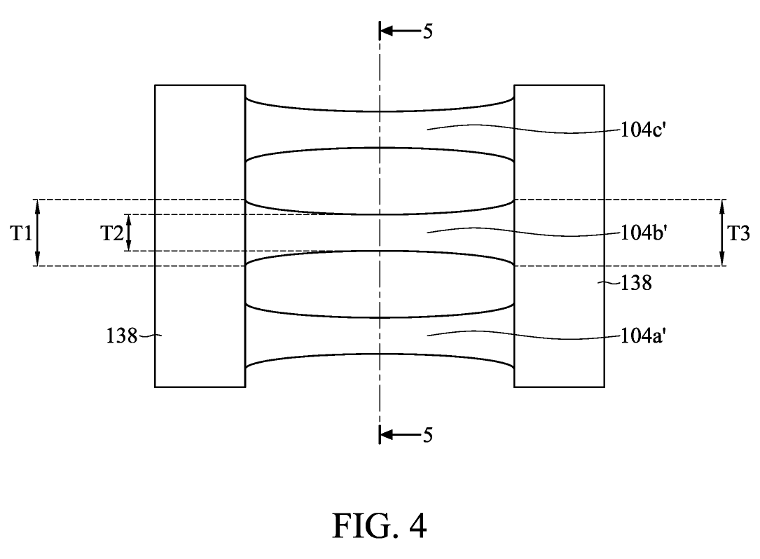

FIG. 4 is a cross-sectional view of an intermediate stage of a process for forming a portion of a semiconductor device structure, in accordance with some embodiments. FIG. 4 may show the cross-sectional view of a portion of a semiconductor device structure that is similar to the embodiments illustrated in FIG. 3M. As shown in FIG. 4, similar to the embodiments shown in FIG. 3M, the semiconductor nanostructures 104a’-104c’ are sandwiched between the epitaxial structures 138.

As mentioned above, in some embodiments, the semiconductor nanostructures 104a’-104c’ have improved surface roughness. As shown in FIG. 4, the semiconductor nanostructure 104b’ has a first thickness T1 at one end and a third thickness T3 at the opposite end. The semiconductor nanostructure 104b’ also has a second thickness T2 at the center of the semiconductor nanostructure 104b’. The semiconductor nanostructure 104b’ has a sheet rounding value of “0.5(T1+T3) - T2.” In some embodiments, each of the semiconductor nanostructures 104a’-104c’ has a sheet rounding value ranging from about 0 nm to about 1.9 nm.

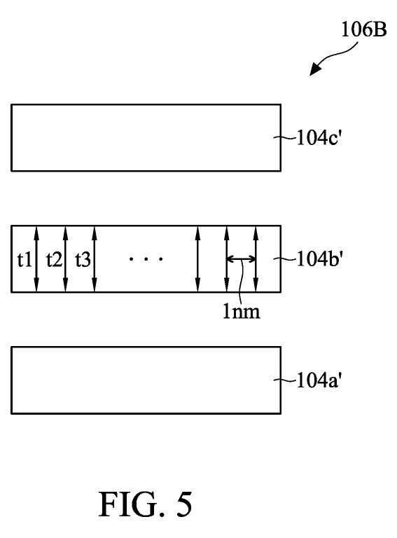

FIG. 5 is a cross-sectional view of an intermediate stage of a process for forming a portion of a semiconductor device structure, in accordance with some embodiments. FIG. 5 may show the cross-sectional view of a portion of a semiconductor device structure that is similar to the embodiments illustrated in FIG. 4. In some embodiments, FIG. 5 is a cross-sectional view of the structure taken along the line 5-5 in FIG. 4.

As mentioned above, in some embodiments, the semiconductor nanostructures 104a’-104c’ have improved surface roughness. As shown in FIG. 5, the semiconductor nanostructure 104b’ has multiple thicknesses including the thicknesses t1, t2, t3 and so on. These thicknesses are measured at different sections of the semiconductor nanostructure 104b’. As shown in FIG. 5, the distance between adjacent sections may be uniform, such as 1 nm. In some embodiments, each of the semiconductor nanostructures 104a’-104c’ has a line width roughness (LWR) in a range from about 0 nm to about 0.9 nm. The LWR may describe the variations or roughness along the edges of a patterned line. It quantifies the irregularities and fluctuations in the width or thickness of an element, such as a semiconductor nanostructure. The LWR may be calculated by measuring the line width at multiple points along its length and then determining the standard deviation of these measurements. In some embodiments, the LWR is equal to 7-sigma standard deviation of the semiconductor nanostructure 104b’.

Many variations and/or modifications can be made to embodiments of the disclosure. In some embodiments, the inner spacers 136 have multiple sub-layers.

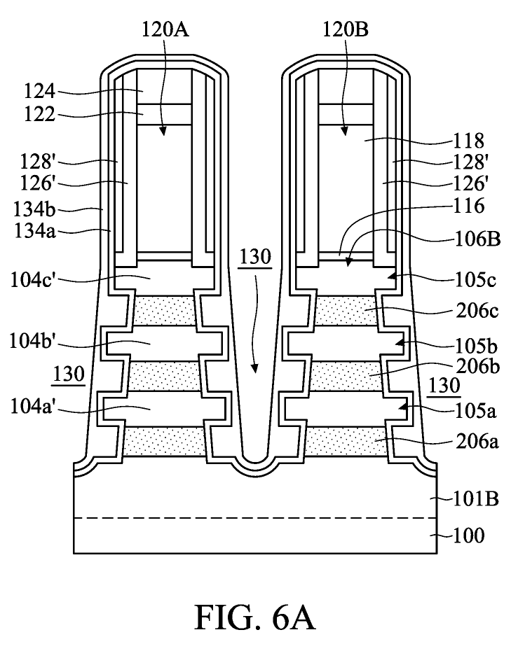

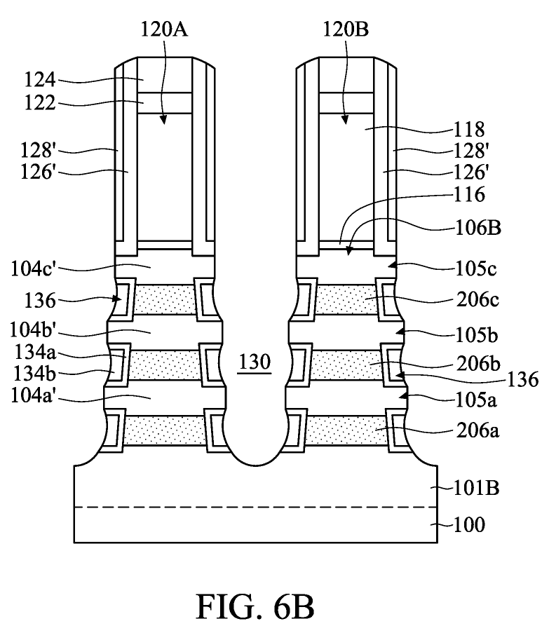

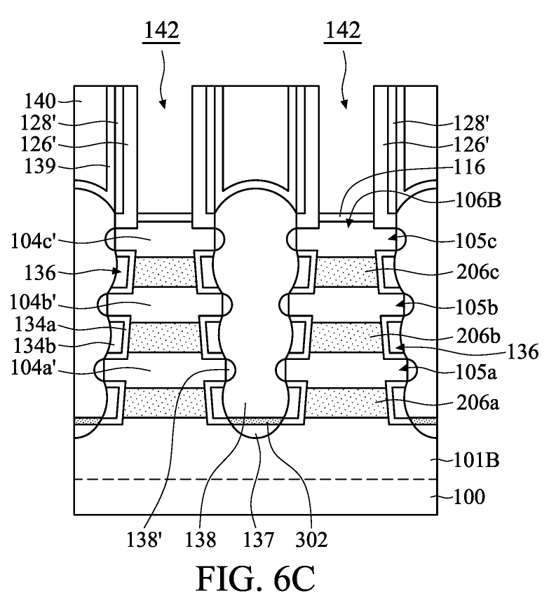

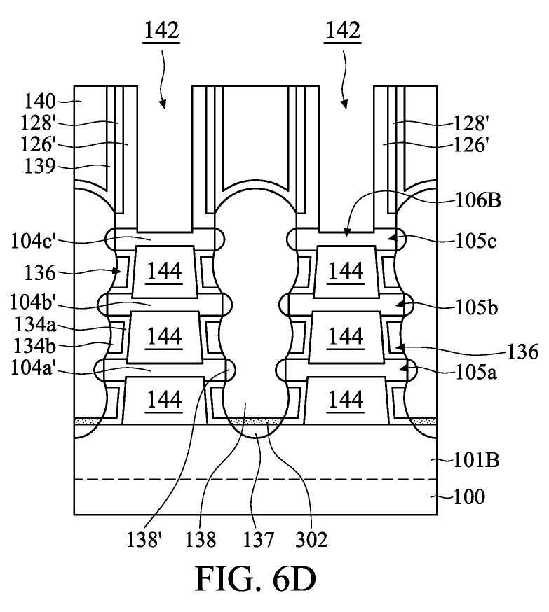

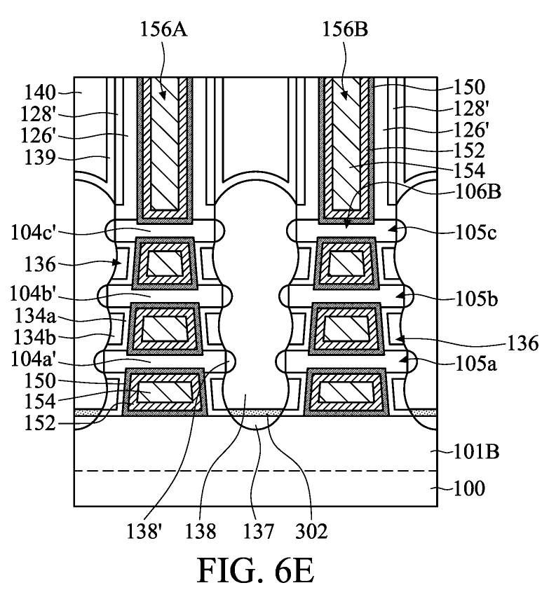

FIGS. 6A-6E are cross-sectional views of various stages of a process for forming portions of a semiconductor device structure, in accordance with some embodiments. As shown in FIG. 6A, a structure that is similar to the structure shown in FIG. 3H is formed. In some embodiments, the insulating layer used for forming the inner spacers includes multiple sub-layers such as the sub-layers 134a and 134b shown in FIG. 6A. In some embodiments, the sub-layers 134a and 134b are made of different materials.

As shown in FIG. 6B, similar to the embodiments shown in FIG. 3I, the sub-layers 134a and 134b are partially removed using one or more etching processes, in accordance with some embodiments. As a result, the remaining portions of the sub-layers 134a and 134b form the inner spacers 136.

Afterwards, the processes that are similar to those shown in FIGS. 3J-3L are performed. As a result, the structure shown in FIG. 6C is formed, in accordance with some embodiments.

As shown in FIG. 6D, similar to the embodiments illustrated in FIG. 3M, the dummy gate dielectric layer 116 and the dielectric nanostructures 206a-206c are removed using an etching process, in accordance with some embodiments. In some embodiments, the sub-layer 134a has a higher etching resistance to the etching process than the sub-layer 134b. Therefore, the sub-layer 134a may prevent the epitaxial structures 138 from being damaged by the etching process used for removing the dielectric nanostructures 206a-206c. In some embodiments, the sub-layer 134b has a lower dielectric constant than that of the sub-layer 134a, which may help to reduce the total dielectric constant of the inner spacers 136. The inner spacers 136, with their low dielectric constant, may help reduce parasitic capacitance between the epitaxial structures 138 and the metal gate stacks that will be formed later. This reduction in parasitic capacitance may lead to an improvement in the operational speed of the semiconductor device structure.

As shown in FIG. 6E, similar to the embodiments shown in FIG. 3N, the metal gate stacks 156A and 156B are formed, in accordance with some embodiments.

In some embodiments, multiple dielectric nanostructures 206a-206c are formed to replace the semiconductor layers 102a-102c before the formation of the epitaxial structures 138. However, embodiments of the disclosure are not limited thereto. Many variations and/or modifications can be made to embodiments of the disclosure. In some other embodiments, the semiconductor layers 102a-102c are not replaced with dielectric nanostructures.

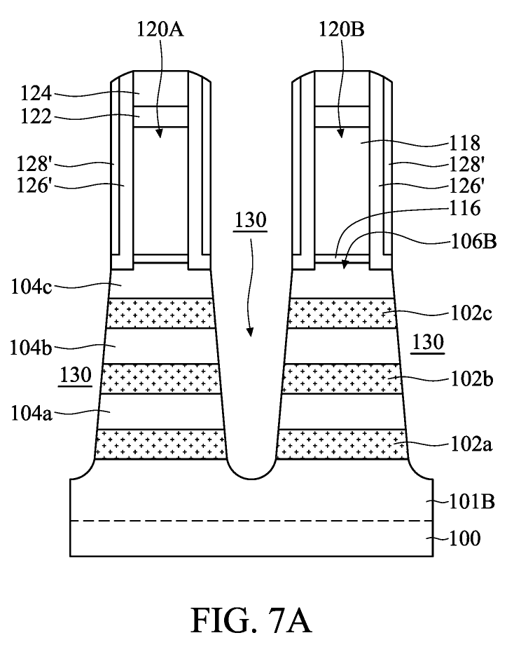

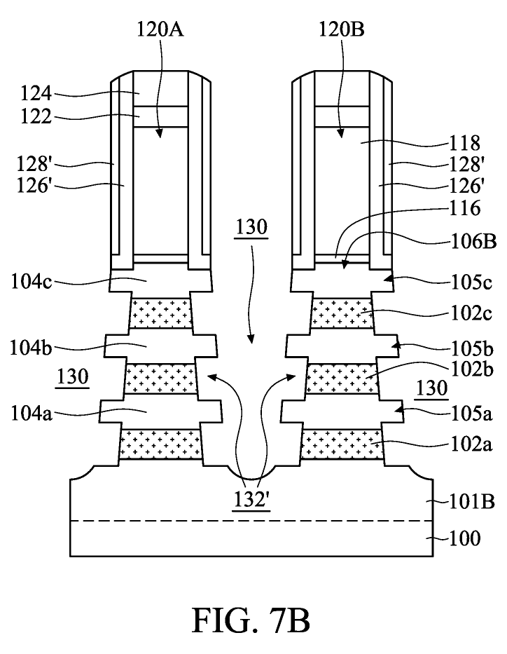

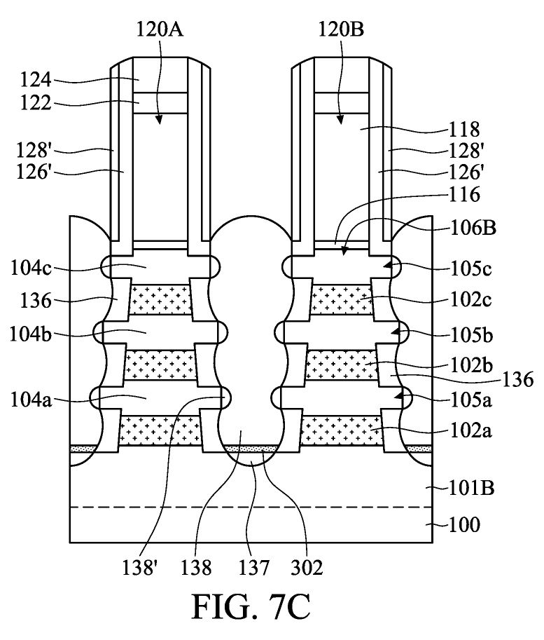

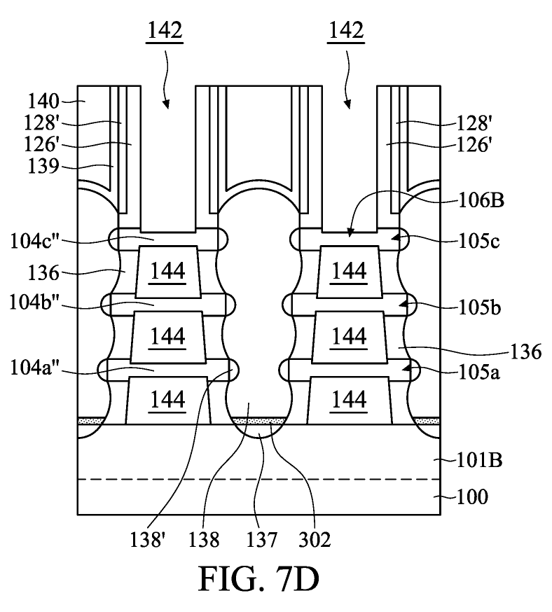

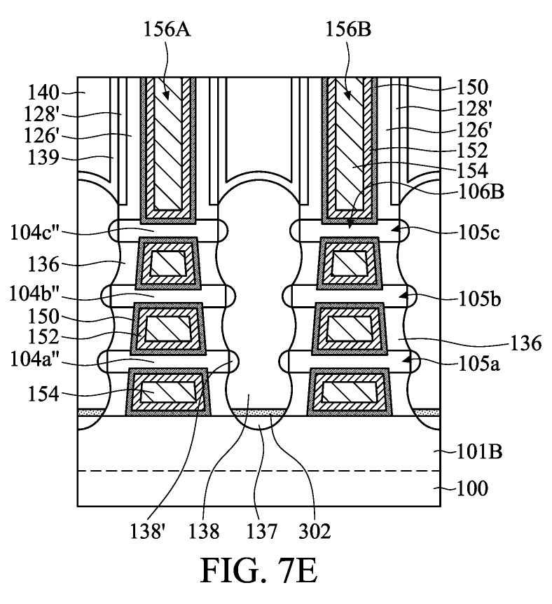

FIGS. 7A-7E are cross-sectional views of various stages of a process for forming portions of a semiconductor device structure, in accordance with some embodiments. As shown in FIG. 7A, a structure that is the same as or similar to that shown in FIG. 3C is formed.

Afterwards, as shown in FIG. 7B, similar to the embodiments illustrated in FIG. 3G, the semiconductor layers 102a-102c are laterally etched to form multiple recesses 132’, in accordance with some embodiments.

Then, the processes that are similar to those illustrated in FIGS. 3H-3J are performed. As a result, the structure shown in FIG. 7C is formed. The thermal process used to form the epitaxial structures 138 may cause germanium impurities to diffuse from the semiconductor layers 102a-102c into the semiconductor layers 104a-104c. The semiconductor layers 104a-104c may thus exhibit a relatively high atomic concentration of germanium impurities near their interface with the semiconductor layers 102a-102c.

Afterwards, the processes that are similar to those shown in FIGS. 3K-3M are performed. As a result, the structure shown in FIG. 7D is formed, in accordance with some embodiments. After the removal of the semiconductor layers 102a-102c, the remaining portions of the semiconductor layers 104a-104c that are released form semiconductor nanostructures 104a”, 104b”, and 104c”, as shown in FIG. 7D.

Some germanium impurities may still remain in the semiconductor nanostructures 104a”-104c” after the semiconductor layers 102a-102c are removed. The semiconductor nanostructures 104a”-104c” may have an atomic concentration of germanium impurities that is in a range from about 0.02% to about 0.1%. In some embodiments, due to the high atomic concentration of germanium impurities of the semiconductor layers 104a-104c, the obtained semiconductor nanostructures 104a”-104c” may have relatively rough surfaces. In some embodiments, each of the semiconductor nanostructures 104a”-104c” has a sheet rounding value ranging from about 2.2 nm to about 2.5 nm. In some embodiments, each of the semiconductor nanostructures 104a”-104c” has a line width roughness (LWR) in a range from about 1.4 nm to about 1.8 nm.

Afterwards, similar to the embodiments shown in FIG. 3N, the metal gate stacks 156A and 156B are formed, as shown in FIG. 7E in accordance with some embodiments.

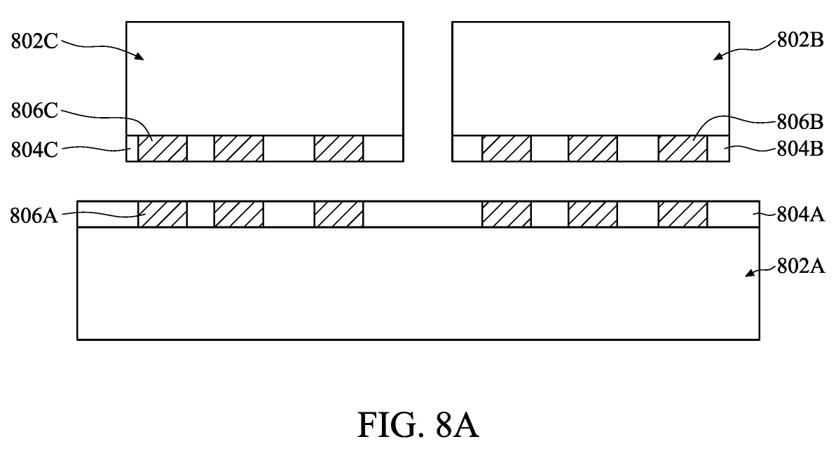

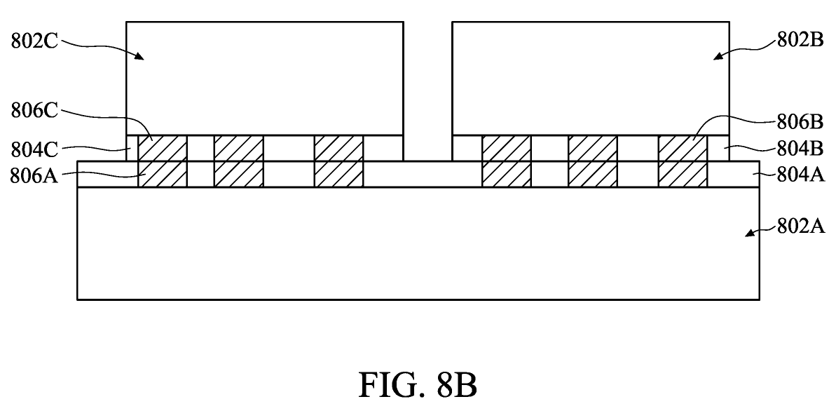

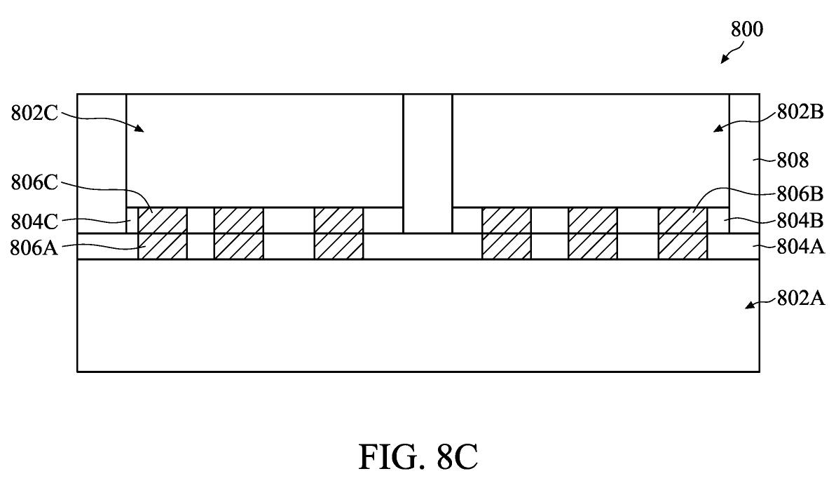

Many variations and/or modifications can be made to embodiments of the disclosure. FIGS. 8A-8C are cross-sectional views of various stages of a process for forming portions of a semiconductor device structure, in accordance with some embodiments. As shown in FIG. 8A, multiple chip-containing structures 802A, 802B, and 802C are formed or received. In some embodiments, the chip-containing structures 802A, 802B, and 802C are semiconductor chips that will be integrated together. In some embodiments, the transistor devices in one or more of the chip-containing structures 802A, 802B, and 802C are formed using the processes illustrated in FIGS. 3A-3N and/or 6A-6E. In some embodiments, the transistor devices in one or more of the chip-containing structures 802A, 802B, and 802C are formed using the processes illustrated in FIGS. 7A-7E.

In some embodiments, the chip-containing structures 802A, 802B, and 802C include dielectric bonding structures 804A, 804B, and 804C and metal bonding structures 806A, 806B, and 806C. The formation of the dielectric bonding structures 804A-804C and the metal bonding structures 806A-806C involve planarization processes such as chemical mechanical polishing (CMP) processes. The planarization processes provide the chip-containing structures 802A, 802B, and 802C with highly planarized bonding surfaces.

As shown in FIG. 8B, the chip-containing structure 802A-802C are bonded together through direct bonding, in accordance with some embodiments. The direct bonding may be a hybrid bonding that includes metal-to-metal bonding and dielectric-to-dielectric bonding. For example, the dielectric bonding structures 804A and 804B are in direct contact with each other and together form the dielectric-to-dielectric bonding. Similarly, the dielectric bonding structures 804A and 804C are in direct contact with each other and together form the dielectric-to-dielectric bonding. The metal bonding structures 806A and 806B are in direct contact with each other and together form the metal-to-metal bonding. Similarly, the metal bonding structures 806A and 806C are in direct contact with each other and together form the metal-to-metal bonding. In some embodiments, there is no tin-containing solder elements formed between the chip-containing structures 802A and 802B or between the chip-containing structures 802A and 802C.

In some embodiments, the chip-containing structures 802B and 802C are placed directly on the dielectric bonding structure 804A and the metal bonding structures 806A of the chip-containing structures 802A. As a result, these chip-containing structures 802A-802C are bonded together.

As mentioned above, before the placing of the chip-containing structures 802B and 802C, planarization processes are performed, so as to provide highly planarized bonding surfaces. In some embodiments, a thermal operation is then used to enhance the bonding between the metal bonding structures 806A-806C. The temperature of the thermal operation may be within a range from about 100 degrees C to about 500 degrees C. In some embodiments, there is no tin-containing solder element formed between the chip-containing structures 802A and 802B or between the chip-containing structures 802A and 802C.

As shown in FIG. 8C, a protective layer 808 is then formed to laterally surround the chip-containing structures 802B and 802C, in accordance with some embodiments. As a result, a semiconductor device structure 800 is formed. The protective layer 808 may be made of or include silicon oxide, silicon oxynitride, carbon-containing silicon oxide, epoxy-based molding material, another suitable material, or a combination thereof.

In some embodiments, the transistor devices in the chip-containing structure 802A are formed using the process illustrated in FIGS. 7A-7E, and the transistor devices in the chip-containing structure 802B are formed using the process illustrated in FIGS. 3A-3N or 6A-6E. In some embodiments, the chip-containing structure 802B includes semiconductor nanostructures 104a’-104c’ as illustrated in FIGS. 3A-3N or 6A-6E, and the chip-containing structure 802A includes semiconductor nanostructures 104a”-104c” as illustrated in FIGS. 7A-7E. In some embodiments, the semiconductor nanostructures 104a’-104c’ in the chip-containing structure 802B has a lower atomic concentration of germanium impurities than that of the semiconductor nanostructures 104a”-104c” in the chip-containing structure 802A.

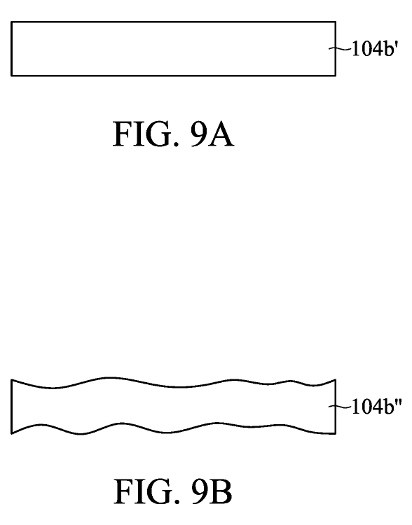

FIG. 9A is a cross-sectional view of a portion of a semiconductor device structure, in accordance with some embodiments. FIG. 9B is a cross-sectional view of a portion of a semiconductor device structure, in accordance with some embodiments. In some embodiments, FIG. 9A shows one of the semiconductor nanostructures 104b’ formed in the chip-containing structure 802B in FIG. 8C, and FIG. 9B shows one of the semiconductor nanostructures 104b” formed in the chip-containing structure 802A in FIG. 8C.

As mentioned above, in some embodiments, the formation of the chip-containing structure 802B involves the processes illustrated in FIGS. 3A-3N or 6A-6E, in which dielectric nanostructures 206a-206c are formed to replace the semiconductor layers 102a-102c that contain germanium. Therefore, germanium is prevented from diffusing into the semiconductor nanostructures 104a’-104c’ during the subsequent thermal processes. The semiconductor nanostructures 104a’-104c’ may thus have smooth and straight profile. As shown in FIG. 9A, one of the semiconductor nanostructures 104b’ is shown. The semiconductor nanostructures 104b’ has a smooth top surface and a smooth bottom surface, resulting in low electrical resistance.

As mentioned above, in some embodiments, the formation of the chip-containing structure 802A involves the processes illustrated in FIGS. 7A-7E, in which no dielectric nanostructures 206a-206c are formed to replace the semiconductor layers 102a-102c that contain germanium. Therefore, germanium may diffuse into the semiconductor nanostructures 104a”-104c” during subsequent thermal processes, leading to a rough surface condition of the semiconductor nanostructures 104a”-104c”. As shown in FIG. 9B, one of the semiconductor nanostructures 104b” is shown. The semiconductor nanostructures 104b” has a rough top surface and a rough bottom surface. In some embodiments, the semiconductor nanostructures 104a”-104c” in the chip-containing structure 802A have a greater line width roughness than that of the semiconductor nanostructures 104a’-104c’ in the chip-containing structure 802B. In some embodiments, the semiconductor nanostructures 104a”-104c” in the chip-containing structure 802A have a greater sheet rounding than that of the semiconductor nanostructures 104a’-104c’ in the chip-containing structure 802B.

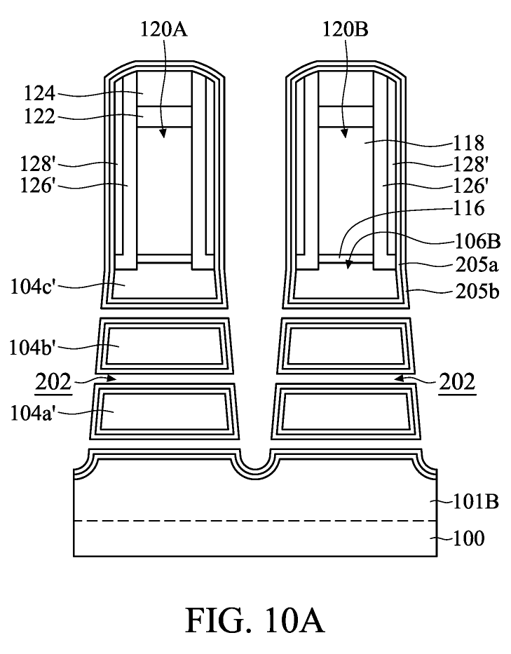

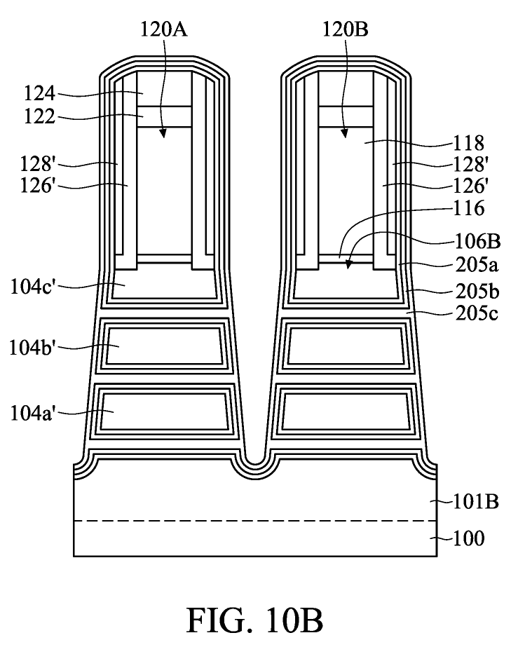

Many variations and/or modifications can be made to embodiments of the disclosure. In some embodiments, each of the dielectric nanostructures includes multiple sub-layers. FIGS. 10A-10B are cross-sectional views of various stages of a process for forming a portion of a semiconductor device structure, in accordance with some embodiments.

As shown in FIG. 10A, a structure that is the same as or similar to the structure shown in FIG. 3D is formed. Afterwards, multiple dielectric sub-layers 205a and 205b are sequentially deposited to partially fill the recesses 202, as shown in FIG. 10A in accordance with some embodiments. In some embodiments, the dielectric sub-layers 205a and 205b are made of the same material. In some other embodiments, the dielectric sub-layers 205a and 205b are made of different materials. For example, the dielectric sub-layers 205a and 205b are carbon-containing silicon oxynitride with different compositions. In some embodiments, the dielectric sub-layers 205a and 205b are deposited using an ALD process.

As shown in FIG. 10B, a dielectric sub-layer 205c is deposited to fill the remaining space of the recesses 202, in accordance with some embodiments. In some embodiments, the dielectric sub-layers 205a-205c are made of the same material. In some other embodiments, the dielectric sub-layer 205c is made of a dielectric material different than that of the dielectric sub-layer 205a or 205c. The dielectric sub-layers 205a-205c may be made of or include silicon oxide, silicon oxynitride, aluminum oxide, silicon nitride, another suitable material, or a combination thereof.

In some embodiments, the dielectric sub-layer 205c is deposited using a deposition process that has a better gap-filling ability than that used for depositing the dielectric sub-layer 205b. In some embodiments, the dielectric sub-layer 205c is deposited using an FCVD process. In some embodiments, the formation of the dielectric sub-layers 205a-205c includes one or more etching processes to adjust their profiles, ensuring the complete filling of the recesses 202.

Afterwards, the process that is similar to the embodiments illustrated in FIG. 3F is performed to partially remove the dielectric sub-layers 205a-205c. As a result, multiple dielectric nanostructures are formed, in accordance with some embodiments.

Many variations and/or modifications can be made to embodiments of the disclosure. In some embodiments, there are three channel structures (such as the semiconductor nanostructures 104a’-104c’) formed between the nearby epitaxial structures 138. However, embodiments of the disclosure are not limited thereto. Many variations and/or modifications can be made to embodiments of the disclosure. In some embodiments, the total number of semiconductor nanostructures between the nearby epitaxial structures 138 is greater than three. In some other embodiments, the total number of semiconductor nanostructures between the nearby epitaxial structures 138 is smaller than three. The total number of semiconductor nanostructures (or channel structures) between the nearby epitaxial structures 138 may be fine-tuned to meet requirements. For example, the total number of semiconductor nanostructures between the nearby epitaxial structures 138 may be between 2 and 10. The semiconductor nanostructures may have many applicable profiles. The semiconductor nanostructures may include nanosheets, nanowires, or other suitable nanostructures.

Embodiments of the disclosure form a semiconductor device structure with multiple semiconductor nanostructures. Before the formation of epitaxial structures between which the semiconductor nanostructures are formed, the semiconductor sacrificial layers between the semiconductor nanostructures are replaced with dielectric nanostructures. Thus, during the thermal processes for forming the epitaxial structures, the germanium-containing semiconductor sacrificial layers had already been removed. As a result, the diffusion of germanium impurities into the semiconductor nanostructures is significantly reduced or prevented. Consequently, the semiconductor nanostructures maintain a low atomic concentration of germanium impurities, resulting in a smooth and straight profile. This greatly enhances the quality and reliability of the semiconductor device structure.

In accordance with some embodiments, a method for forming a semiconductor device structure is provided. The method includes forming multiple semiconductor nanostructures and multiple semiconductor sacrificial nanostructures over a substrate. The semiconductor nanostructures and the semiconductor sacrificial nanostructures are laid out in an alternating manner. The method also includes replacing the semiconductor sacrificial nanostructures with dielectric nanostructures and forming inner spacers over side edges of the dielectric nanostructures. The method further includes forming an epitaxial structure on side edges of the semiconductor nanostructures and the inner spacers.

In accordance with some embodiments, a method for forming a semiconductor device structure is provided. The method includes forming multiple semiconductor layers and multiple sacrificial layers over a substrate. The semiconductor layers and the sacrificial layers are laid out in an alternating manner. The method also includes forming a dummy gate stack partially covering the semiconductor layers and the sacrificial layers and partially removing the semiconductor layers and the sacrificial layers to form a recess exposing side edges of the semiconductor layers and the sacrificial layers after the dummy gate stack is formed. The method further includes replacing the sacrificial layers with a plurality of dielectric nanostructures after the recess is formed. Remaining portions of the semiconductor layers form a plurality of semiconductor nanostructures. In addition, the method includes forming an epitaxial structure on side edges of the semiconductor nanostructures and removing the dummy gate stack and the dielectric nanostructures. The method also includes forming a metal gate stack wrapped around the semiconductor nanostructures.

In accordance with some embodiments, a semiconductor device structure is provided. The semiconductor device structure includes multiple semiconductor nanostructures and a gate stack wrapped around the semiconductor nanostructures. The semiconductor nanostructures have a line width roughness in a range from about 0 nm to about 0.9 nm. The semiconductor device structure also includes a first epitaxial structure and a second epitaxial structure. The semiconductor nanostructures are sandwiched between the first epitaxial structure and the second epitaxial structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device structure, comprising:
a plurality of semiconductor nanostructures, wherein the semiconductor nanostructures exhibit a line width roughness under about 0.9 nm;
a gate stack wrapped around the semiconductor nanostructures, wherein the gate stack has a gate dielectric layer and a titanium-containing work function layer;
a first epitaxial structure and a second epitaxial structure, wherein at least one of the semiconductor nanostructures is sandwiched between the first epitaxial structure and the second epitaxial structure; and
a dielectric layer laterally surrounding the gate stack and covering the epitaxial structure, wherein the gate dielectric layer has a greater dielectric constant than that of the dielectric layer.

2. The semiconductor device structure as claimed in claim 1, wherein the semiconductor nanostructures have a sheet rounding in a range from about 0 nm to about 1.9 nm.

3. The semiconductor device structure as claimed in claim 1, further comprising:
a first chip-containing structure, wherein the semiconductor nanostructures, the first epitaxial structure, and the second epitaxial structure are within the first chip-containing structure;
a plurality of second semiconductor nanostructures;
a third epitaxial structure and a fourth epitaxial structure, wherein the second semiconductor nanostructures are sandwiched between the third epitaxial structure and the fourth epitaxial structure; and
a second chip-containing structure bonded to the first chip-containing structure through dielectric-to-dielectric bonding and metal-to-metal bonding, wherein the second semiconductor nanostructures, the third epitaxial structure, and the fourth epitaxial structure are within the second chip-containing structure.

4. The semiconductor device structure as claimed in claim 3, wherein the second semiconductor nanostructures have a second line width roughness greater than the line width roughness of the semiconductor nanostructures.

5. The semiconductor device structure as claimed in claim 3, wherein the second semiconductor nanostructures have a second sheet rounding greater than the sheet rounding of the semiconductor nanostructures.

6. The semiconductor device structure as claimed in claim 3, wherein the second semiconductor nanostructures have a higher atomic concentration of germanium impurities than that of the semiconductor nanostructures.

7. The semiconductor device structure as claimed in claim 3, wherein there is no tin-containing solder element formed between the first chip-containing structure and the second chip-containing structure.

8. The semiconductor device structure as claimed in claim 1, wherein:
one of the semiconductor nanostructures has an intermediate portion and an edge portion,
the edge portion is between the intermediate portion and the first epitaxial structure, and the edge portion, and
the edge portion and the intermediate portion have different thicknesses.

9. The semiconductor device structure as claimed in claim 8, wherein the edge portion is thicker than the intermediate portion.

10. A semiconductor device structure, comprising:
a plurality of semiconductor nanostructures extending lengthwise along a first direction, wherein the semiconductor nanostructures have a sheet rounding in a range from about 0 nm to about 1.9 nm;
a gate stack wrapped around the semiconductor nanostructures, wherein the gate stack extends lengthwise along a second direction different from the first direction, and the gate stack has a gate dielectric layer and a gate electrode;
a gate spacer extending along a sidewall of the gate stack, wherein the gate spacer is thicker than the gate dielectric layer; and
an epitaxial structure beside the semiconductor nanostructures.

11. The semiconductor device structure as claimed in claim 10, wherein the semiconductor nanostructures have a line width roughness in a range from about 0 nm to about 0.9 nm.

12. The semiconductor device structure as claimed in claim 11, further comprising:
a first chip-containing structure, wherein the semiconductor nanostructures, the gate stack, and the epitaxial structure are within the first chip-containing structure;
a plurality of second semiconductor nanostructures;
a second epitaxial structure beside the second semiconductor nanostructures;
a second gate stack wrapped around the second semiconductor nanostructures; and
a second chip-containing structure bonded to the first chip-containing structure through dielectric-to-dielectric bonding and metal-to-metal bonding, wherein the second semiconductor nanostructures, the second epitaxial structure, and the second gate stack are within the second chip-containing structure.

13. The semiconductor device structure as claimed in claim 12, wherein the second semiconductor nanostructures have a second line width roughness greater than the line width roughness of the semiconductor nanostructures.

14. The semiconductor device structure as claimed in claim 12, wherein the second semiconductor nanostructures have a second sheet rounding greater than the sheet rounding of the semiconductor nanostructures.

15. The semiconductor device structure as claimed in claim 12, wherein the semiconductor nanostructures have a lower atomic concentration of germanium impurities than that of the second semiconductor nanostructures.

16. A semiconductor device structure, comprising:
a plurality of first semiconductor nanostructures;
a first gate stack wrapped around the first semiconductor nanostructures;
a first source/drain structure beside the first semiconductor nanostructures;
a plurality of second semiconductor nanostructures, wherein the first semiconductor nanostructures have a lower line width roughness than that of the second semiconductor nanostructures, and the first semiconductor nanostructures have a lower sheet rounding than that of the second semiconductor nanostructures;
a second gate stack wrapped around the second semiconductor nanostructures; and
a second source/drain structure beside the second semiconductor nanostructures.

17. The semiconductor device structure as claimed in claim 16, wherein the first semiconductor nanostructures have a lower atomic concentration of germanium impurities than that of the second semiconductor nanostructures.

18. The semiconductor device structure as claimed in claim 16, wherein the first semiconductor nanostructures are within a first chip-containing structure, the second semiconductor nanostructures are within a second chip-containing structure, and the first chip-containing structure is bonded to the second chip-containing structure.

19. The semiconductor device structure as claimed in claim 18, wherein there is no tin-containing solder element between the first chip-containing structure and the second chip-containing structure.

20. The semiconductor device structure as claimed in claim 16, wherein the first semiconductor nanostructures have a line width roughness in a range from about 0 nm to about 0.9 nm.
